(19) United States
(12) Patent Application Publication
(10) Pub. No.: US 2026/0302138 A1
(43) Pub. Date: Oct. 1, 2026

(54) SHOWER HEAD AND PLASMA PROCESSING APPARATUS INCLUDING THE SAME AND METHOD OF MANUFACTURING A SEMICONDUCTOR DEVICE

(71) Applicant: SAMSUNG ELECTRONICS CO., LTD., Suwon-si (KR)

(72) Inventors: Sangyoon LEE, Suwon-si (KR); Sunjin KIM, Suwon-si (KR)

(73) Assignee: SAMSUNG ELECTRONICS CO., LTD., Suwon-si (KR)

(21) Appl. No.: 19/423,520

(22) Filed: Dec. 17, 2025

(30) Foreign Application Priority Data
Mar. 28, 2025 (KR) 10-2025-0040310

(51) Int. Cl. H01J 37/32

(52) U.S. Cl. CPC H01J 37/3244; H01J 37/32522; H01J 2237/002

(57) ABSTRACT

Provided are a shower head and a plasma processing apparatus including the same and a method of manufacturing a semiconductor device. The shower head includes an upper electrode having a first surface exposed to plasma and a second surface opposite to the first surface; a support member having a coupling surface opposing the second surface of the upper electrode; and a magnetic coupling device disposed on the second surface of the upper electrode and the coupling surface of the support member and magnetically coupling the upper electrode to the support member.

### CROSS-REFERENCE TO RELATED APPLICATIONS

This application claims benefit of priority to Korean Patent Application No. 10-2025-0040310 filed on Mar. 28, 2025, in the Korean Intellectual Property Office, the disclosure of which is incorporated herein by reference in its entirety.

### BACKGROUND

Example embodiments of the present disclosure relate to a shower head and a plasma processing apparatus including the same and a method of manufacturing a semiconductor device.

Generally, in a process of manufacturing a semiconductor device, a plasma processing apparatus may etch a film on a semiconductor substrate or may form a film on a semiconductor substrate using plasma. This plasma processing apparatus may generally include an upper electrode and a lower electrode, and may perform plasma processing on a substrate by generating plasma in a processing space between the upper electrode and the lower electrode.

In the plasma processing apparatus, the upper electrode may be supported by being fastened to a support member, and when fastening force between the upper electrode and the support member is insufficient, a temperature difference may occur between a central portion and an edge portion of the upper electrode during the plasma processing process. In particular, when fastening force for the central portion of the upper electrode is insufficient, a temperature difference between the central portion and the edge portion of the upper electrode may gradually increase, and defects such as breakage of the upper electrode may occur.

### SUMMARY

An example embodiment of the present disclosure is to provide a shower head which may improve heat transfer efficiency.

An example embodiment of the present disclosure is to provide a plasma processing apparatus including a shower head which may improve heat transfer efficiency.

An example embodiment of the present disclosure is to provide a method of manufacturing a semiconductor device using a plasma processing apparatus which may improve heat transfer efficiency.

According to an example embodiment of the present disclosure, a shower head includes an upper electrode having a first surface exposed to plasma and a second surface opposite to the first surface; a support member having a coupling surface opposing the second surface of the upper electrode; and a magnetic coupling device disposed on the second surface of the upper electrode and the coupling surface of the support member and magnetically coupling the upper electrode to the support member.

According to an example embodiment of the present disclosure, a plasma processing apparatus includes a chamber having a processing space; a chuck disposed in the processing space of the chamber, supporting a substrate and including a lower electrode; and a shower head disposed in an upper portion of the chamber and opposing the chuck, wherein the shower head includes an upper electrode having a first surface exposed to plasma and a second surface opposite to the first surface; a cooling plate having a coupling surface opposing the second surface of the upper electrode; and a magnetic coupling device disposed between the second surface of the upper electrode and the coupling surface of the cooling plate and magnetically coupling the upper electrode to the cooling plate.

According to an example embodiment of the present disclosure, a method of manufacturing a semiconductor device includes loading a substrate into a chamber including a shower head disposed in an upper portion of the chamber; and supplying a first processing gas through the shower head into the chamber in which the substrate is loaded, exciting the processing gas in a plasma state and plasma-processing the substrate, wherein the shower head includes an upper electrode having a first surface exposed to plasma and a second surface opposite to the first surface; a support member having a coupling surface opposing the second surface of the upper electrode; and a magnetic coupling device disposed on the second surface of the upper electrode and the coupling surface of the support member and magnetically coupling the upper electrode to the support member.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a diagram illustrating a plasma processing apparatus according to an example embodiment of the present disclosure;

FIG. 2 is a diagram illustrating a shower head according to an example embodiment of the present disclosure;

FIG. 3 is a diagram illustrating an upper electrode and a support member of a shower head according to an example embodiment of the present disclosure;

FIG. 4 is an exploded diagram of FIG. 3;

FIG. 5 is a plan diagram illustrating a magnetic coupling device and an external magnetic field distribution of a shower head according to an example embodiment of the present disclosure;

FIG. 6 is a cross-sectional diagram illustrating a portion of a coupling portion of an upper electrode, a support member, and a magnetic coupling device of a shower head according to an example embodiment of the present disclosure;

FIG. 7 is a diagram illustrating an upper electrode and a support member of a shower head according to an example embodiment of the present disclosure;

FIG. 8 is a diagram illustrating an upper electrode and a support member of a shower head according to an example embodiment of the present disclosure;

FIG. 9 is a diagram illustrating an upper electrode and a support member of a shower head according to an example embodiment of the present disclosure;

FIG. 10 is a diagram illustrating an upper electrode and a support member of a shower head according to an example embodiment of the present disclosure;

FIG. 11 is a diagram illustrating an upper electrode and a support member of a shower head according to an example embodiment of the present disclosure;

FIG. 12 is a diagram illustrating a plasma processing apparatus according to an example embodiment of the present disclosure; and

FIG. 13 is a diagram illustrating a plasma processing apparatus according to an example embodiment of the present disclosure.

### DETAILED DESCRIPTION

Hereinafter, embodiments of the present disclosure will be described as follows with reference to the accompanying drawings.

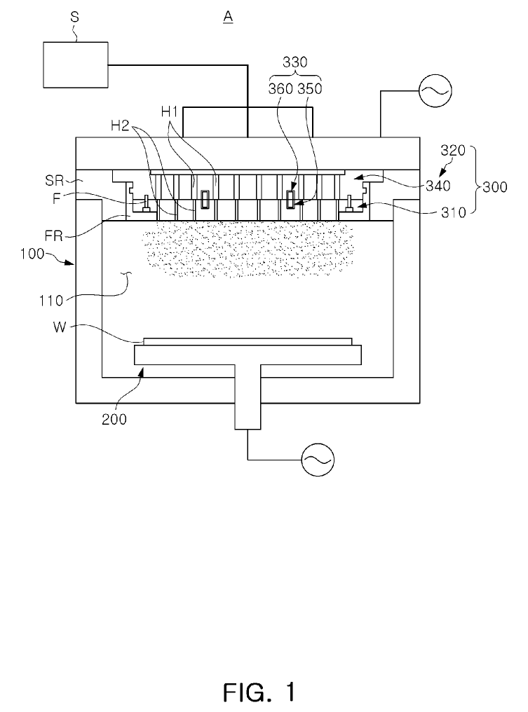

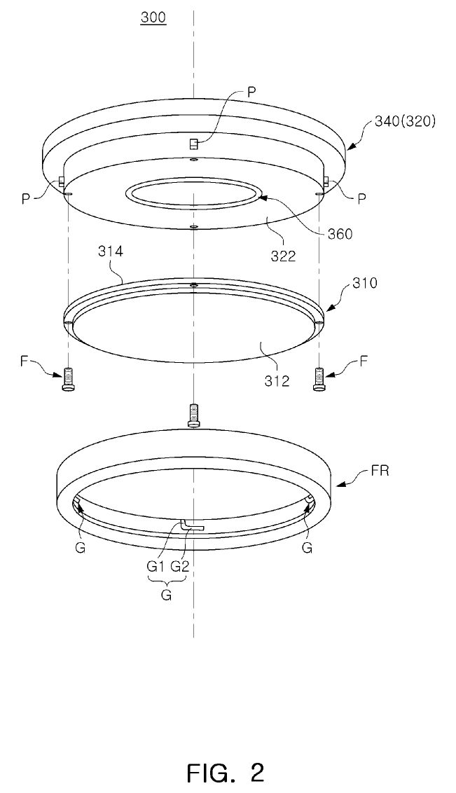

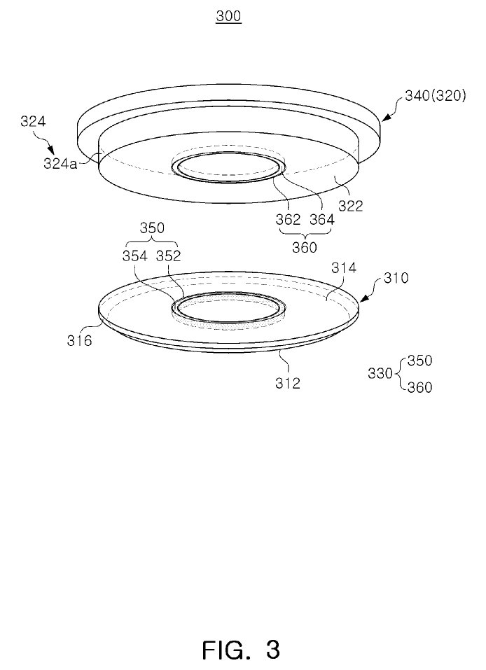

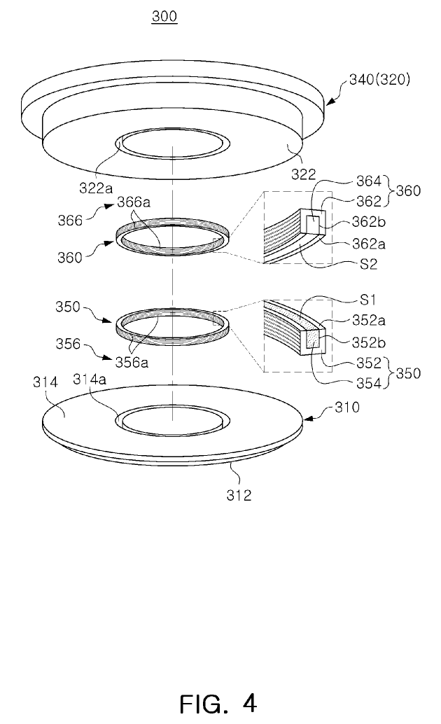

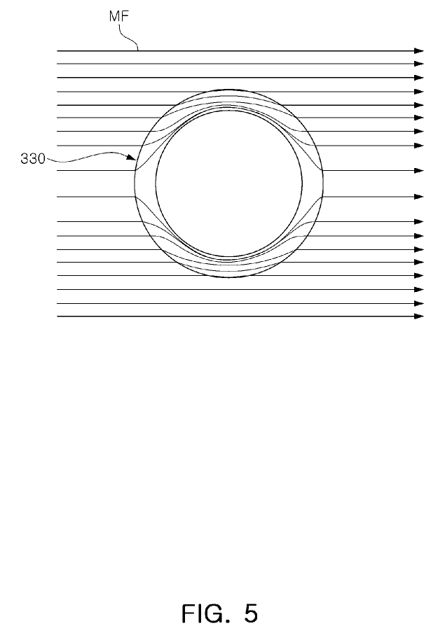

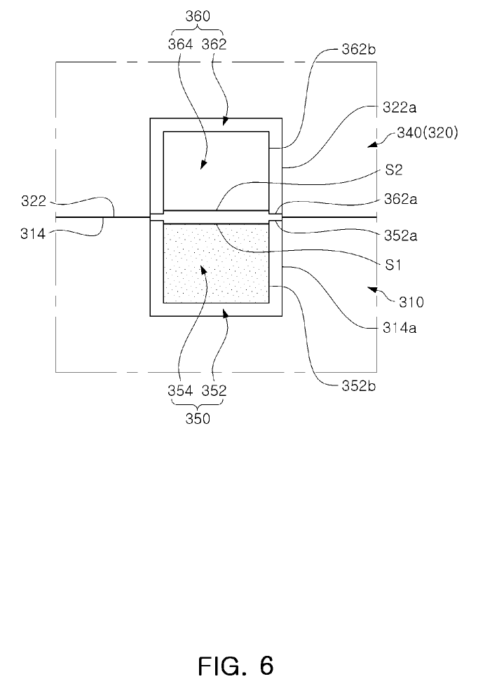

FIG. 1 is a diagram illustrating a plasma processing apparatus according to an example embodiment. FIG. 2 is a diagram illustrating a shower head according to an example embodiment. FIG. 3 is a diagram illustrating an upper electrode and a support member of a shower head according to an example embodiment. FIG. 4 is an exploded diagram of FIG. 3. FIG. 5 is a plan diagram illustrating a magnetic coupling device and an external magnetic field distribution of a shower head according to an example embodiment. FIG. 6 is a cross-sectional diagram illustrating a portion of a coupling portion of an upper electrode, a support member, and a magnetic coupling device of a shower head according to an example embodiment.

Referring to FIGS. 1-6, a plasma processing apparatus A according to an example embodiment may include a chamber 100, a chuck 200, and a shower head 300.

The chamber 100 may include a processing space 110. The plasma processing apparatus A may process a substrate using plasma in the processing space 110 of the chamber 100. The plasma processing apparatus A may perform an etching process or a deposition process for the substrate W. The plasma processing apparatus A may generate plasma in various manners. In an example embodiment, the plasma processing apparatus A may be a capacitively coupled plasmas (CCP) device, but an example embodiment thereof is not limited thereto, and the plasma processing apparatus A may be various plasma processing apparatuses such as an inductively coupled plasmas (ICP) device, for example.

The chuck 200 may be disposed in the processing space 110 of the chamber 100 and may support the substrate W. In an example embodiment, the chuck 200 may be an electrostatic chuck connected to a high-voltage direct current power source and supporting and fixing the substrate W to a setting position by electrostatic power generated by a current applied to the chuck 200. However, the chuck 200 is not limited thereto, and may be implemented as various chucks, such as a chuck fixing the substrate W using a mechanical device such as a clamp. The chuck 200 may include a lower electrode (not illustrated) generating plasma for plasma processing the substrate W together with the upper electrode 310 of the shower head 300, which will be described later. The lower electrode may have a disk shape in the chuck 200, but an example embodiment thereof is not limited thereto. The lower electrode RF of the chuck 200 may be connected to the power source, and RF power may be applied from the RF power source. Plasma in the processing space 110 of the chamber 100 may be controlled by the RF power applied to the lower electrode. In an example embodiment, the chuck 200 may include a temperature adjusting module for adjusting the temperature of the chuck 200 or the substrate W. In an example embodiment, the chuck 200 may include a heater therein, a cooling plate for cooling the lower electrode, or the like. In an example embodiment, the heater may include a heating wire, and the cooling plate may have a refrigerant flow path formed therein through which a refrigerant flows.

The shower head 300 may be disposed in an upper portion of the chamber 100 and may oppose the chuck 200. In an example embodiment, the shower head 300 may be disposed in an upper portion of the chamber 100 through a support ring SR. The support ring SR may be formed of an insulating material, such as ceramic, for example. The shower head 300 may include an upper electrode 310, a support member 320, and a magnetic coupling device 330.

The upper electrode 310 may have a first surface 312 exposed to plasma and a second surface 314 opposite to the first surface 312. The first surface 312 of the upper electrode 310 may be exposed to the processing space 110 of the chamber 100 and may oppose the chuck 200, and the second surface 314 of the upper electrode 310 may be positioned opposite to the first surface 312 of the upper electrode 310 and may oppose the support member 320. The upper electrode 310 may be connected to an RF power source and RF power may be applied from the RF power source. The plasma in the processing space 110 of the chamber 100 may be controlled by the RF power applied to the upper electrode 310. The RF power source connected to the upper electrode 310 and the RF power source connected to the lower electrode may be the same or separate power sources. Plasma may be generated by the processing space 110 of the chamber 100 by the upper electrode 310 of the shower head 300 and the lower electrode of the chuck 200, such that the substrate W disposed on the chuck 200 may be plasma processed. The upper electrode 310 may include a plurality of gas supply holes H1 for supplying gas. A processing gas required for plasma processing of the substrate may be supplied to the processing space 110 through the plurality of gas supply holes H1 of the upper electrode 310.

The support member 320 may be coupled to the second surface 314 of the upper electrode 310 and may hold the upper electrode 310. The support member 320 may have a coupling surface 322 opposing the second surface 314 of the upper electrode 310. The support member 320 may include a plurality of gas flow holes H2 connected to a gas supply source S supplying a process gas necessary for plasma processing and communicated with the gas supply hole H1 of the upper electrode 310. The support member 320 may include a function of cooling the shower head 300. In an example embodiment, the support member 320 may include a cooling plate 340 including the coupling surface 322. The cooling plate 340 may include a refrigerant flow path through which a refrigerant flows therein. The cooling plate 340 may be disposed on the second surface 314 of the upper electrode 310, and one surface of the cooling plate 340 disposed on the second surface 314 of the upper electrode 310 may be implemented as a coupling surface 322 of the support member 320. The refrigerant flowing in the flow path in the cooling plate 340 may be a heat-conducting fluid such as brine or gas, but an example embodiment thereof is not limited thereto. The cooling plate 340 may be coupled to the upper electrode 310 and may maintain the upper electrode 310 at a constant temperature during the plasma processing process, thereby preventing an abnormal temperature increase of the upper electrode 310. Also, in an example embodiment, the support member 320 may include a heater for heating the upper electrode 310.

The upper electrode 310 and the support member 320 may be formed in a disk shape, but an example embodiment thereof is not limited thereto, and may be formed in various shapes. The upper electrode 310 and the support member 320 may be coupled to each other in various manners. In an example embodiment, as illustrated in FIGS. 1 and 2, the outer edge 316 of the upper electrode 310 and the outer edge 324 of the support member 320 may be fastened to each other by various fastening means. In an example embodiment, the shower head 300 may include at least one of a fastening member F connecting the outer edge 316 of the upper electrode 310 and the outer edge 324 of the support member 320 or a fastening ring FR disposed between the outer edge 316 of the first surface 312 of the upper electrode 310 and the outer circumferential surface 324a of the support member 320 and connected to the support member 320. The shower head 300 may include both the fastening member F and the fastening ring FR. The fastening member F may be implemented as a fastening bolt and may penetrate the outer edge 316 of the upper electrode 310 and the outer edge 324 of the support member 320 in the height direction and may fasten the upper electrode 310 to the support member 320 by screw-thread connection. As the fastening ring FR, various materials may be used, and for example, quartz, or the like may be used, but an example embodiment thereof is not limited thereto. The fastening ring FR may have a ring shape and may cover a lower surface and an outer circumferential surface of the outer edge 316 of the upper electrode 310 and an outer circumferential surface 324a of the outer edge 324 of at least a portion of the support member 320. The fastening ring FR may cover the fastening member F such that the fastening member F may not be exposed to the processing space 110 of the chamber 100. The fastening ring FR may be connected to the outer edge 324 of the support member 320. To connect the fastening ring FR to the support member 320, a plurality of coupling projections may be disposed on one of the internal circumferential surface of the fastening ring FR or the outer circumferential surface 324a of at least a portion of the support member 320, and a plurality of coupling grooves in which the plurality of coupling projections are correspondingly inserted and fixed may be disposed on the other. In an example embodiment, as illustrated in FIG. 2, the plurality of coupling projections P may be disposed on the outer circumferential surface 324a of at least a portion of the support member 320, and a plurality of coupling grooves G to which the plurality of coupling projections P are correspondingly inserted and fixed are disposed in the internal circumferential surface of the fastening ring FR. In an example embodiment, each of the plurality of coupling grooves G may include a first groove portion G1 and a second groove portion G2. The first groove portion G1 may extend in the height direction of the fastening ring FR on the internal circumferential surface of the fastening ring FR, and the second groove portion G2 may extend to be downwardly inclined in one direction so as to have a predetermined angle with the height direction from the lower end of the first groove portion G1 on the internal circumferential surface of the fastening ring FR. Accordingly, while the upper electrode 310 and the support member 320 are coupled to each other, the coupling projection P of the support member 320 may be inserted into the first groove portion G1 of the coupling groove G of the fastening ring FR, and the coupling projection P of the support member 320 may be inserted into and fixed to the second groove portion G2 of the coupling groove G by rotating the upper electrode 310 and the support member 320 in a direction opposite to the extension direction of the second groove portion G2. Accordingly, the upper electrode 310 and the support member 320 may be coupled to each other by the fastening member F and the fastening ring FR. Conversely, the upper electrode 310 and the support member 320 may isolate the fastening ring FR from the support member 320 by rotating in the opposite direction, opposite to the one direction. Accordingly, the operation of detaching and attaching the fastening ring FR may be easily implemented. The coupling means for coupling the fastening ring FR to the support member 320 are described in the form of coupling projection P and coupling groove G, but an example embodiment thereof is not limited thereto, and the fastening ring FR and the support member 320 may be coupled by various coupling means such as bolts. Also, the fastening ring FR is described to be directly coupled to the support member 320, but if desired, the fastening ring FR may be implemented to be coupled to at least one of the support member 320 or the upper electrode 310.

In the description above, both the fastening member F and the fastening ring FR are included, but an example embodiment thereof is not limited thereto, and the shower head 300 may also include only the fastening member F or the fastening ring FR.

Generally, in the case of plasma processing apparatus, a gap may be formed between the upper electrode and the support member due to various factors such as insufficient fastening force between the upper electrode of the shower head and the support member supporting the upper electrode, and in particular, a gap may be formed between the central region of the upper electrode and the support member. The shower head may thermally expand due to heating, and as the gap between the upper electrode and the support member gradually widens due to thermal expansion, the cooling efficiency for the upper electrode may decrease and defects such as breakage of the upper electrode may also occur.

To prevent this, a magnetic coupling device 330 may be disposed between the upper electrode 310 and the support member 320. The magnetic coupling device 330 may be disposed on the second surface 314 of the upper electrode 310 and the coupling surface 322 of the support member 320, and may magnetically couple the upper electrode 310 to the support member 320.

The magnetic coupling device 330 may be implemented in various example embodiments. In an example embodiment, the magnetic coupling device 330 may include at least one first magnetic coupling member 350 and at least one second magnetic coupling member 360 magnetically coupled to the at least one first magnetic coupling member 350. In an example embodiment, as illustrated in FIGS. 1-4, the magnetic coupling device 330 may include one first magnetic coupling member 350 and one second magnetic coupling member 360. The first magnetic coupling member 350 may be disposed on the second surface 314 of the upper electrode 310, and the second magnetic coupling member 360 may be disposed on the coupling surface 322 of the support member 320 and may be magnetically coupled to the first magnetic coupling member 350.

In an example embodiment, the first magnetic coupling member 350 may include a first magnetic shield member 352 and a first magnetic member 354. A first accommodation groove 352b may be disposed on one surface 352a of the first magnetic shield member 352 facing the second surface 314 of the upper electrode 310. The first magnetic member 354 may be accommodated in the first accommodation groove 352b of the first magnetic shield member 352. The first magnetic member 354 may include a first magnetic adsorption surface S1 exposed from the first accommodation groove 352b. The first magnetic shield member 352 may surround the first magnetic member 354 so as to expose the first magnetic adsorption surface S1 of the first magnetic member 354. The second magnetic coupling member 360 may include a second magnetic shield member 362 and a second magnetic member 364. A second accommodation groove 362b corresponding to the first accommodation groove 352b may be disposed on one surface 362a of the second magnetic shield member 362 facing the coupling surface 322 of the support member 320. The second magnetic member 364 may be accommodated in the second accommodation groove 362b of the second magnetic shield member 362. The second magnetic member 364 may include a second magnetic adsorption surface S2 exposed from the second accommodation groove 362b. The second magnetic shield member 362 may surround the second magnetic member 364 so as to expose the second magnetic adsorption surface S2 of the second magnetic member 364.

The first magnetic adsorption surface S1 of the first magnetic member 354 and the second magnetic adsorption surface S2 of the second magnetic member 364 may generate magnetic adsorption force to each other, and the second surface 314 of the upper electrode 310 and the coupling surface 322 of the support member 320 may be closely coupled to each other by the magnetic adsorption force of the first magnetic coupling member 350 and the second magnetic coupling member 360. In this case, the first magnetic shield member 352 and the second magnetic shield member 362 may surround the first magnetic member 354 and the second magnetic member 364, and may block the formation of a magnetic field externally of the first magnetic shield member 352 and the second magnetic shield member 362, and may strengthen the magnetic adsorption force of the first magnetic adsorption surface S1 of the first magnetic member 354 and the second magnetic adsorption surface S2 of the second magnetic member 364.

According to the above configuration, the plasma processing apparatus A may continuously maintain the second surface 314 of the upper electrode 310 and the coupling surface 322 of the support member 320 to be in close contact with and coupled to each other without a gap between the upper electrode 310 and the support member 320 during the plasma processing process for the substrate W by the magnetic adsorption force of the first magnetic coupling member 350 and the second magnetic coupling member 360, thereby reinforcing the fastening force between the upper electrode 310 and the support member 320, and thus improving the heat transfer efficiency (especially the cooling efficiency) of the shower head 300 and further effectively preventing defects such as breakage of the upper electrode 310.

The first magnetic shield member 352 and the second magnetic shield member 362 may reduce external influences. In an example embodiment, to control the shape of the plasma in the plasma processing apparatus A, when a method of forming a magnetic field in the processing space 110 in the chamber 100 using an electromagnet externally of the chamber 100 during the plasma processing process is used, the first magnetic shield member 352 and the second magnetic shield member 362 may reduce interference effects on the magnetic field distribution in the processing space 110 of the chamber 100.

The first magnetic shield member 352 and the second magnetic shield member 362 may include various materials. In an example embodiment, the first magnetic shield member 352 and/or the second magnetic shield member 362 may include a material having high magnetic permeability and low coercivity. In an example embodiment, the first magnetic shield member 352 and/or the second magnetic shield member 362 may include one of ferrite, mu-metal, or supermalloy. As illustrated in FIG. 5, the first magnetic shield member 352 and the second magnetic shield member 362 including the material may prevent an external magnetic field MF generated by an electromagnet provided for plasma control from entering the first magnetic shield member 352 and the second magnetic shield member 362, and may also reduce the interference effect on the magnetic field distribution of chamber 100 generated by the electromagnet. However, the material is not limited to the material of the first magnetic shield member 352 and the second magnetic shield member 362, and may include other materials having high magnetic permeability and low coercivity.

The first magnetic member 354 and the second magnetic member 364 may include various materials. In an example embodiment, the first magnetic member 354 and the second magnetic member 364 may include a material having high temperature resistance. In an example embodiment, the first magnetic member 354 and/or the second magnetic member 364 may be one of an AlNiCo magnet, a samarium cobalt (SmCo) magnet or a neodymium (NdFeB) magnet, preferably an AlNiCo magnet or a samarium cobalt magnet. However, the material is not limited to the material of the first magnetic member 354 and the second magnetic member 364, and the magnet may be formed of another material having high temperature resistance.

In an example embodiment, the first magnetic coupling member 350 may be disposed adjacently to the central region of the upper electrode 310 on the second surface 314 of the upper electrode 310. The first magnetic shield member 352 may be configured to have various shapes. In an example embodiment, the first magnetic shield member 352 may have a ring shape and may be disposed concentrically with the shower head 300 on the second surface 314 of the upper electrode 310. The first accommodation groove 352b may be disposed in a ring shape in a circumferential direction of the first magnetic shield member 352 on one surface 352a of the first magnetic shield member 352. The first magnetic shield member 352 may have a “U”-shaped cross-sectional shape in which the opening direction of the first accommodation groove 352b is directed upwardly. The first magnetic member 354 may be formed in various shapes in the first accommodation groove 352b, and in an example embodiment the first magnetic member 354 may have a ring shape corresponding to the shape of the first accommodation groove 352b, but an example embodiment thereof is not limited thereto.

In an example embodiment, the second magnetic coupling member 360 may be disposed adjacently to the central region of the support member 320 on the coupling surface 322 of the support member 320. In an example embodiment, the second magnetic shield member 362 may have a ring shape and may be disposed concentrically with the shower head 300 on the coupling surface 322 of the support member 320. The second accommodation groove 362b may be disposed in a ring shape in a circumferential direction of the second magnetic shield member 362 on one surface 362a of the second magnetic shield member 362. The second magnetic shield member 352 may have a cross-sectional shape of an inverted “U” shape in which the opening direction of the second accommodation groove 362b is directed downwardly. The second magnetic member 364 may be formed in various shapes in the second accommodation groove 362b, and in an example embodiment, the second magnetic member 364 may have a ring shape corresponding to the shape of the second accommodation groove 362b, but an example embodiment thereof is not limited thereto.

As the first magnetic coupling member 350 and the second magnetic coupling member 360 are disposed adjacently to the central region of the shower head 300, the fastening force for the central region of the upper electrode 310 and the support member 320 may be strengthened, and a gap in the central region of the upper electrode 310 and the support member 320 may be effectively prevented.

However, in the example embodiment, the arrangement position and shape of the first magnetic coupling member 350 and the second magnetic coupling member 360 are not limited to the arrangement position and shape described above, and may be disposed in an appropriate position between the center and the outer edge of the shower head 300 and may be configured to have various shapes.

In an example embodiment, the first magnetic coupling member 350 may be inserted into the second surface 314 of the upper electrode 310. The first seating groove 314a in which the first magnetic shield member 352 is accommodated may be disposed on the second surface 314 of the upper electrode 310. The opening direction of the first accommodation groove 352b of the first magnetic shield member 352 may be the same as the opening direction of the first seating groove 314a. Accordingly, in the first magnetic coupling member 350, when the first magnetic shield member 352 is disposed in the first seating groove 314a, the first magnetic adsorption surface S1 of the first magnetic member 354 may be exposed from the opening of the first accommodation groove 352b and the first seating groove 314a. The second magnetic coupling member 360 may be inserted into the coupling surface 322 of the support member 320. A second seating groove 322a in which the second magnetic shield member 362 is accommodated may be disposed on the coupling surface 322 of the support member 320. The opening direction of the second accommodation groove 362b of the second magnetic shield member 362 may be the same as the opening direction of the second seating groove 322a. Accordingly, in the second magnetic coupling member 360, when the second magnetic shield member 362 is disposed in the second seating groove 322a, the second magnetic adsorption surface S2 of the second magnetic member 364 may be exposed from the opening of the second accommodation groove 362b and the second seating groove 322a and may oppose the first magnetic adsorption surface S1 of the first magnetic member 354. Assembly holes to which fixing devices for mounting to the first seating groove 314a of the upper electrode 310 and the second seating groove 322a of the support member 320 are connected may be formed in one surface 352a of the first magnetic shield member 352 and one surface 362a of the second magnetic shield member 362, respectively, but an example embodiment thereof is not limited thereto.

The magnetically coupling between the first magnetic coupling member 350 and the second magnetic coupling member 360 may include configuring the first magnetic adsorption surface S1 of the first magnetic member 354 of the first magnetic coupling member 350 and the second magnetic adsorption surface S2 of the second magnetic member 364 of the second magnetic coupling member 360 to be in contact with each other and magnetically coupled to or to not be in contact with each other and magnetically coupled to each other with a gap therebetween by a magnetic adsorption force.

In an example embodiment, the one surface 352a of the first magnetic shield member 352 may be positioned at a level lower than or the same as the second surface 314 of the upper electrode 310 in the height direction of the shower head 300. The first magnetic adsorption surface S1 of the first magnetic member 354 may be positioned at a level lower than or the same level as the one surface 352a of the first magnetic shield member 352 in the height direction of the shower head 300. In an example embodiment, as illustrated in FIG. 6, the first magnetic adsorption surface S1 of the first magnetic member 354 may be positioned at a level lower than the second surface 314 of the upper electrode 310, and the one surface 352a of the first magnetic shield member 352 may be positioned at a level between the first magnetic adsorption surface S1 of the first magnetic member 354 and the second surface 314 of the upper electrode 310, in the height direction of the shower head 300.

In an example embodiment, the one surface 362a of the second magnetic shield member 362 may be positioned at a level higher than or the same as the coupling surface 322 of the support member 320 in the height direction of the shower head 300. The second magnetic adsorption surface S2 of the second magnetic member 364 may be positioned at a level higher than or the same level as the one surface 362a of the second magnetic shield member 362 in the height direction of the shower head 300. In an example embodiment, as illustrated in FIG. 6, the second magnetic adsorption surface S2 of the second magnetic member 364 may be positioned at a level higher than the coupling surface 322 of the support member 320, and the one surface 362a of the second magnetic shield member 362 may be positioned at a level between the second magnetic adsorption surface S2 of the second magnetic member 364 and the coupling surface 322 of the support member 320, in the height direction of the shower head 300. Thermal expansion may occur in the first magnetic coupling member 350 and the second magnetic coupling member 360 due to high temperature. Even when thermal expansion occurs in the first magnetic coupling member 350 and the second magnetic coupling member 360, by configuring the first magnetic coupling member 350 to be disposed at a level lower than the level of the second surface 314 of the upper electrode 310 and the second magnetic coupling member 360 to be disposed at a level higher than the level of the coupling surface 322 of the support member 320, the second surface 314 of the upper electrode 310 and the coupling surface 322 of the support member 320 may be maintained to be in contact with each other, and accordingly, the fastening force between the upper electrode 310 and the support member 320 may be effectively ensured such that a gap may not be formed between the upper electrode 310 and the support member 320.

In an example embodiment, the first magnetic shield member 352 may be disposed to be attached to and removed from the first seating groove 314a formed in the second surface 314 of the upper electrode 310 by the first fastening portion 356. The first fastening portion 356 may be implemented in various forms. In an example embodiment, the first fastening portion 356 may include a first screw thread 356a formed on at least one of the internal circumferential surface or the outer circumferential surface of the first magnetic shield member 352 and a second screw thread (not illustrated) formed on at least one of the internal circumferential surface or the outer circumferential surface of the first seating groove 314a, and a second screw thread screw thread-connected to the first screw thread 356a. For example, as illustrated in FIG. 4, the first screw thread 356a may be formed on the internal circumferential surface and the outer circumferential surface of the first magnetic shield member 352, and the second screw thread may be formed on the internal circumferential surface and the outer circumferential surface of the first seating groove 314a. Accordingly, by rotation of the first magnetic coupling member 350 and/or the upper electrode 310, the first magnetic coupling member 350 may be easily attached to and removed from the first seating groove 314a of the upper electrode 310, and stable connection with the first seating groove 314a may be implemented. The first fastening portion 356 is described as including the first screw thread 356a and the second screw thread, but an example embodiment thereof is not limited thereto, and the first fastening portion 356 may be implemented in various forms, such as including the coupling groove G and the coupling projection P applied by coupling the fastening ring and the support member.

In an example embodiment, the second magnetic shield member 362 may be disposed to be attached to and removed from a second seating groove 322a formed on the coupling surface 322 of the support member 320 by the second fastening portion 366. The second fastening portion 366 may be implemented in various forms. In an example embodiment, the second fastening portion 366 may include a third screw thread 366a formed on at least one of the internal circumferential surface or the outer circumferential surface of the second magnetic shield member 362 and a fourth screw thread (not illustrated) formed on at least one of the internal circumferential surface or the outer circumferential surface of the second seating groove 322a and screw thread-connected to the third screw thread 366a. For example, as illustrated in FIG. 4, the third screw thread 366a may be formed on the internal circumferential surface and the outer circumferential surface of the second magnetic shield member 362, and the fourth screw thread may be formed on the internal circumferential surface and the outer circumferential surface of the second seating groove 322a. Accordingly, the second magnetic coupling member 360 may be easily attached to and removed from the second seating groove 322a of the support member 320 by rotation of the second magnetic coupling member 360 and/or the support member 320, and stable connection with the second seating groove 322a may be implemented. Although the second fastening portion 366 is described as including the third screw thread 366a and the fourth screw thread, but an example embodiment thereof is not limited thereto, and the second fastening portion 366 may be implemented in various forms, such as including the coupling groove G and the coupling projection P applied by coupling the fastening ring and the support member.

In the description above, the magnetic coupling device 330 is described as including a first magnetic coupling member 350 and a second magnetic coupling member 360, but an example embodiment thereof is not limited thereto, and the magnetic coupling device 330 may include a plurality of first magnetic coupling members and a plurality of second magnetic coupling members corresponding to the number of the first magnetic coupling member, which will be described in the example embodiments below.

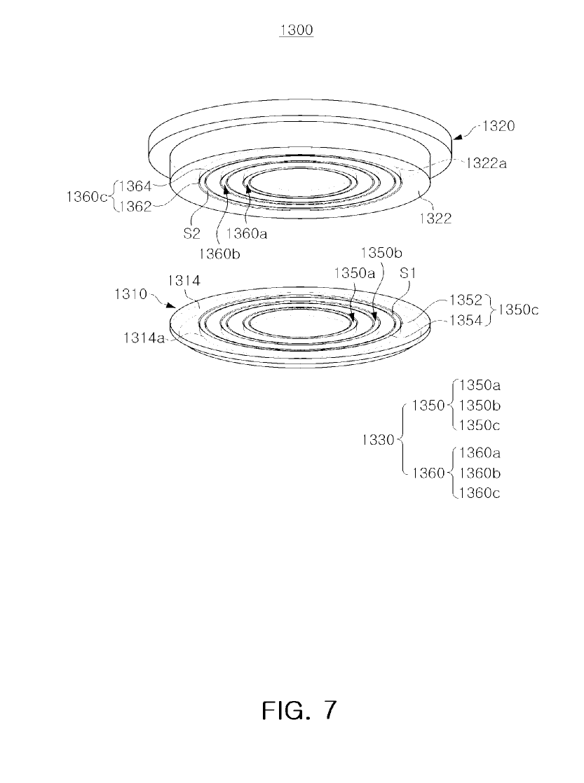

FIG. 7 is a diagram illustrating an upper electrode and a support member of a shower head according to an example embodiment.

Referring to FIG. 7, a plasma processing apparatus A according to an example embodiment may include a chamber, a chuck, and a shower head 1300.

Components of the chamber and the chuck may be the same as components of the chamber 100 and the chuck 200 described in the aforementioned example embodiment, and the overlapping description thereof will not be provided.

A plasma processing apparatus A according to an example embodiment may include the fastening member F and/or the fastening ring FR described in the aforementioned example embodiment.

The shower head 1300 may include an upper electrode 1310, a support member 1320, and a magnetic coupling device 1330.

The upper electrode 1310 and the support member 1320 may include components included in the upper electrode 310 and the support member 320 described in the aforementioned example embodiment, and the overlapping description thereof will not be provided.

The magnetic coupling device 1330 may include a plurality of first magnetic coupling member 1350 and a plurality of second magnetic coupling members 1360 corresponding to the plurality of first magnetic coupling members 1350. In this case, a plurality of first seating grooves 1314a in which the plurality of first magnetic coupling members 1350 are accommodated in a corresponding manner may be disposed on the second surface 1314 of the upper electrode 1310, and a plurality of second seating grooves 1322a in which the plurality of second magnetic coupling members 1360 are accommodated in a corresponding manner may be disposed on the coupling surface 1322 of the support member 1320.

Each of the first magnetic coupling members 1350 may include the first magnetic shield member 1352 and the first magnetic member 1354. The shapes of the first magnetic shield member 1352 and the first magnetic member 1354 may be the same as the shapes of the first magnetic shield member 352 and the first magnetic member 354 described in the aforementioned example embodiment, but an example embodiment thereof is not limited thereto. Each of the first magnetic shield members 1352 may have a ring shape. Each of the first magnetic shield members 1352 may be spaced apart from the shower head 1300 in a concentric shape on the second surface 1314 of the upper electrode 1310. That is, the plurality of first magnetic coupling members 1350 may have different diameters. Each of the first accommodation grooves 1352b of the first magnetic shield member 1352 may be disposed in a ring shape in a circumferential direction of the first magnetic shield member 1352 on one surface of the first magnetic shield member 1352. Each of the second magnetic shield members 1362 may have a ring shape. Each of the second magnetic shield members 1362 may be spaced apart from the shower head 1300 concentrically on the coupling surface 1322 of the support member 1320. That is, the plurality of second magnetic shield members 1362 may have different diameters. Each of the second accommodation grooves 1362b of the second magnetic shield member 1362 may be disposed in a ring shape in a circumferential direction of the second magnetic shield member 1362 on one surface of the second magnetic shield member 1362. The plurality of first magnetic coupling members 1350 and the plurality of second magnetic coupling members 1360 may correspond to each other and may be magnetically coupled to each other.

The first magnetic member 1354 of the plurality of first magnetic coupling member 1350 may include a first magnetic adsorption surface S1 having the same polarity or opposite polarities. The second magnetic member 1364 of the plurality of second magnetic coupling member 1360 may include a second magnetic adsorption surface S2 having the same polarity or opposite polarities, which correspond to each of the first magnetic member 1354 of the plurality of first magnetic coupling member 1350 and generates a magnetic adsorption force. In an example embodiment, the first magnetic adsorption surface S1 of the first magnetic member 1354 of the first magnetic coupling member 1350b positioned in the middle of the three first magnetic coupling members 1350a, 1350b, and 1350c in FIG. 7 may have an N pole or a S pole, and the first magnetic adsorption surface S1 of the first magnetic member 1354 of the two first magnetic coupling members 1350a and 1350c positioned on both sides may have an S pole or a N pole, but an example embodiment thereof is not limited thereto. In this case, the second magnetic adsorption surface S2 of the second magnetic member 1364 of the second magnetic coupling member 1360b positioned in the middle of the three second magnetic coupling members 1360a, 1360b, and 1360c may have an S pole or an N pole having a polarity opposite to that of the first magnetic adsorption surface S1 of the first magnetic member 1354 of the first magnetic coupling member 1350b positioned in the middle, and the second magnetic adsorption surface S2 of the second magnetic member 1364 of the two second magnetic coupling members 1360a and 1360c positioned on both sides may have an N pole or an S pole having a polarity opposite to that of the first magnetic adsorption surface S1 of the first magnetic member 1354 of the two first magnetic coupling members 1350a and 1350c positioned on both sides, but an example embodiment thereof is not limited thereto.

At least one of the plurality of first magnetic coupling members 1350 may be disposed adjacently to a central region of the upper electrode 1310 on the second surface 1314 of the upper electrode 1310. At least one of the plurality of second magnetic coupling members 1360 may be disposed adjacently to the central region of the support member 1320 on the coupling surface 1322 of the support member 1320 to correspond to the at least one first magnetic coupling member 1350. As illustrated in FIG. 7 in an example embodiment, among the plurality of first magnetic coupling members 1350a, 1350b, and 1350c, the first magnetic coupling member 1350a positioned on an innermost side may be disposed adjacently to the central region of the upper electrode 1310 on the second surface 1314 of the upper electrode 1310, and among the plurality of second magnetic coupling members 1360a, 1360b, and 1360c, the second magnetic coupling member 1360a positioned on an innermost side may be disposed adjacently to the central region of the support member 1320.

The heat transfer efficiency of the shower head 1300 may be improved by further strengthening the fastening force between the upper electrode 1310 and the support member 1320 by the magnetic coupling device 1330 including the plurality of first magnetic coupling members 1350 and the plurality of second magnetic coupling members 1360, and a gap between the upper electrode 1310 and the support member 1320 may be effectively prevented.

In the description above, the magnetic coupling device 330 and 1330 including the first magnetic coupling member 350 and 1350 in which the first magnetic member 354, 1354 is configured in a ring shape in the first accommodation groove 352b and 1352b of the first magnetic shield member 352 and 1352, and the second magnetic coupling member 360 and 1360 in which the second magnetic member 364 and 1364 is configured in a ring shape in the second accommodation groove 362b and 1362b of the second magnetic shield member 362 and 1362 is described as example embodiments, but an example embodiment thereof is not limited thereto, and the first magnetic member and the second magnetic member may be configured in various forms, and is described with reference to the example embodiment below, as an example.

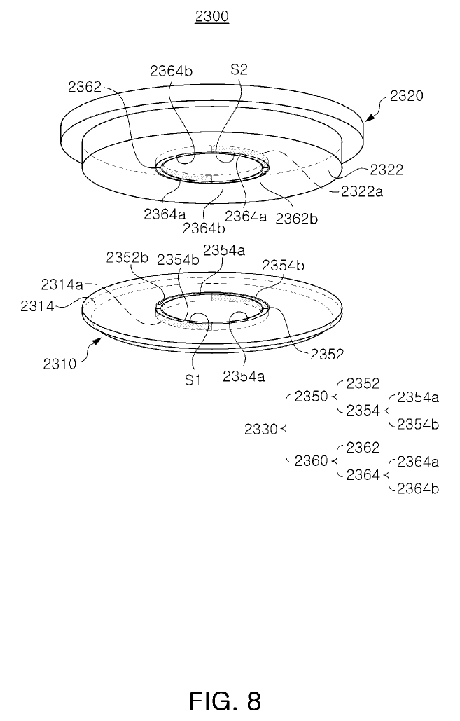

FIG. 8 is a diagram illustrating an upper electrode 2310 and a support member 2320 of a shower head 2300 according to an example embodiment.

Referring to FIG. 8, a magnetic coupling device 2330 according to an example embodiment may include a first magnetic coupling member 2350 including a first magnetic member 2354 disposed in a first accommodation groove 2352b of the first magnetic shield member 2352 and a second magnetic coupling member 2360 including a second magnetic shield member 2362 and a second magnetic member 2364 disposed in the second accommodation groove 2362b of the second magnetic shield member 2362.

In this case, a plurality of first seating grooves 2314a in which the plurality of first magnetic coupling members 2350 are accommodated in a corresponding manner may be disposed on the second surface 2314 of the upper electrode 2310, and a plurality of second seating grooves 2322a in which the plurality of second magnetic coupling members 2360 are accommodated in a corresponding manner may be disposed on the coupling surface 2322 of the support member 2320.

The first magnetic shield member 2352 and the second magnetic shield member 2362 may be the same as the components of the first magnetic shield member 352 and the second magnetic shield member 362 described in the aforementioned example embodiment, and the overlapping description thereof will not be provided.

The first accommodation groove 2352b may be formed in a ring shape on one surface of the first magnetic shield member 2352. The first magnetic member 2354 may be disposed in various shapes in the first accommodation groove 2352b. In an example embodiment, the first magnetic member 2354 may include a plurality of first magnets 2354a and a plurality of second magnets 2354b intersecting and adjacently to each other. The plurality of first magnets 2354a and the plurality of second magnets 2354b may be configured to have the same shape or size or may be configured to have different shapes or sizes. The plurality of first magnets 2354a and the plurality of second magnets 2354b may be included in the first magnetic adsorption surface S1 of the first magnetic member 2354. The plurality of first magnets 2354a and the plurality of second magnets 2354b may have opposite polarities. That is, the magnetic adsorption surface of a portion of the first magnetic adsorption surface S1 including a plurality of first magnets 2354a may have polarities opposite to that of the magnetic adsorption surface of the other portion of the first magnetic adsorption surface S1 including a plurality of second magnets 2354b.

The second magnetic coupling member 2360 may be configured to correspond to the components of the first magnetic coupling member 2350. The second accommodation groove 2362b may be formed in a ring shape on one surface of the second magnetic shield member 2362. The second magnetic member 2364 may be disposed in various forms in the second accommodation groove 2362b. In an example embodiment, the second magnetic member 2364 may include a plurality of third magnet 2364a and a plurality of fourth magnet 2364b disposed intersect and adjacently to each other. The plurality of third magnet 2364a and the plurality of fourth magnet 2364b may be configured to have the same shape or size or may be configured to have different shapes or sizes. The plurality of third magnet 2364a and the plurality of fourth magnet 2364b may be included in the second magnetic adsorption surface S2 of the second magnetic member 2364. The plurality of third magnet 2364a and the plurality of fourth magnet 2364b may have opposite polarities. That is, the magnetic adsorption surface of a portion of the second magnetic adsorption surface S2, which includes the plurality of third magnet 2364a may have opposite polarities to that of the magnetic adsorption surface of the other portion of the second magnetic adsorption surface S2, which includes the plurality of fourth magnet 2364b. The plurality of third magnet 2364a may have the same shape or size as the plurality of first magnets 2354a and may be disposed in corresponding positions. A plurality of magnetic adsorption surfaces of the third magnet 2364a may have polarities opposite to that of the magnetic adsorption surfaces of the first magnets 2354a. A plurality of fourth magnet 2364b may have the same shape or size as the plurality of second magnets 2354b and may be disposed in corresponding positions. A plurality of magnetic adsorption surfaces of the fourth magnet 2364b may have polarities opposite to that of the magnetic adsorption surfaces of the second magnets 2354b.

As described above, the magnetic adsorption force of the first magnetic member 2354 including a plurality of first magnets 2354a and a plurality of second magnets 2354b having opposite polarities and the second magnetic member 2364 including a plurality of third magnet 2364a and a plurality of fourth magnet 2364b having opposite polarities may cause an alignment effect in the circumferential direction of the upper electrode including the first magnetic coupling member 2350 and the support member including the second magnetic coupling member 2360, and may implement the fixed-position fastening between the upper electrode and the support member.

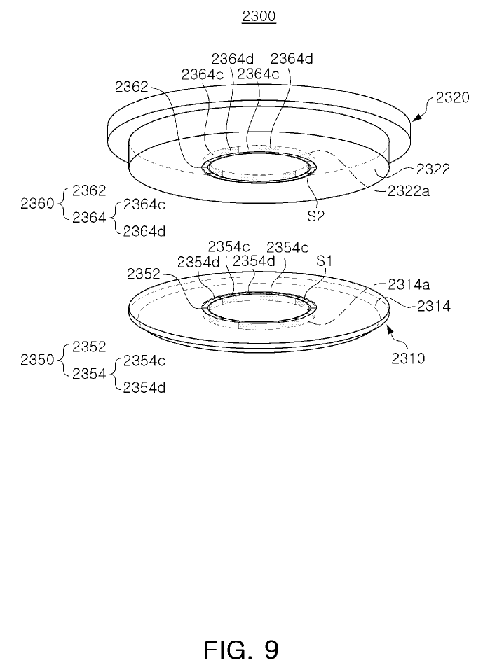

In FIG. 8, the first magnetic member 2354 may include two first magnets 2354a and two second magnets 2354b, and the second magnetic member 2364 may include two third magnets 2364a and two fourth magnets 2364b. However, an example embodiment thereof is not limited thereto, and as another example, as illustrated in FIG. 9, the first magnetic member 2354 may include two or more first magnets 2354c and two or more second magnets 2354d, and the second magnetic member 2364 may include two or more third magnets 2364c and two or more fourth magnets 2364d. Alternatively, as another example, the first magnetic member may include one first magnet and one second magnet, and the second magnetic member may include one third magnet and one fourth magnet.

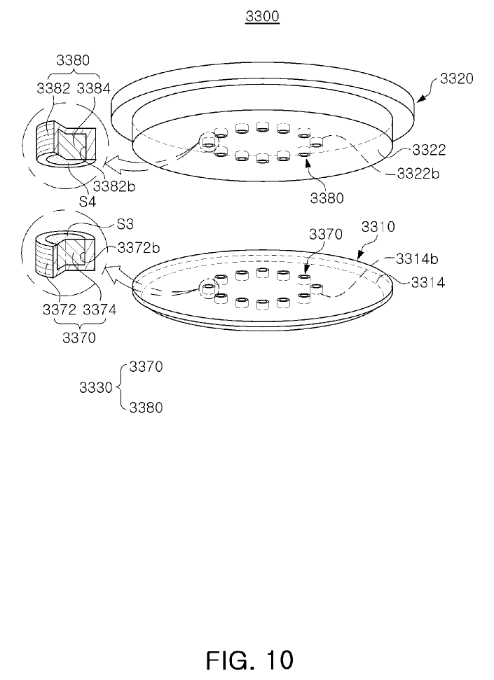

FIG. 10 is a diagram illustrating an upper electrode and a support member of a shower head according to an example embodiment.

Referring to FIG. 10, a plasma processing apparatus A according to an example embodiment may include a chamber 100, a chuck 200, and a shower head 3300.

Components of the chamber 100 and the chuck 200 may be the same as components of the chamber 100 and the chuck 200 described in the aforementioned example embodiment, and the overlapping description thereof will not be provided.

A plasma processing apparatus A according to an example embodiment may include the fastening member F and/or the fastening ring FR described in the aforementioned example embodiment.

The shower head 3300 may include an upper electrode 3310, a support member 3320, and a magnetic coupling device 3330.

The upper electrode 3310 and the support member 3320 may include components included in the upper electrode 310 and the support member 320 described in the aforementioned example embodiment, and the overlapping description thereof will not be provided.

The magnetic coupling device 3330 may include a plurality of third magnetic coupling members 3370 and a plurality of fourth magnetic coupling members 3380 corresponding to the plurality of third magnetic coupling members 3370. The plurality of third magnetic coupling members 3370 may be disposed at each of the plurality of coupling points provided on the second surface 3314 of the upper electrode 3310. The plurality of third magnetic coupling members 3370 may be formed in various shapes, such as a columnar shape, and may be configured in a cylindrical shape, for example. A plurality of fourth magnetic coupling members 3380 may be disposed at a plurality of coupling points provided on the coupling surface 3322 of the support member 3320 and may be magnetically coupled to a plurality of third magnetic coupling members 3370, respectively. The fourth magnetic coupling member 3380 may be formed in the same shape as the third coupling member 3370, and may be configured in a cylindrical shape, for example. In an example embodiment, each of the plurality of third magnetic coupling members 3370 may include a third magnetic shield member 3372 and a third magnetic member 3374 in a cylindrical shape. A third accommodation groove 3372b may be disposed on one surface of the third magnetic shield member 3372 facing the second surface 3314 of the upper electrode 3310. The third magnetic member 3374 may include a third magnetic adsorption surface S3 accommodated in a third accommodation groove 3372b of the third magnetic shield member 3372 and exposed from the third accommodation groove 3372b. Each of the plurality of fourth magnetic coupling members 3380 may include a fourth magnetic shield member 3382 and a fourth magnetic member 3384 having a cylindrical shape. A fourth accommodation groove 3382b corresponding to the third accommodation groove 3372b may be disposed on one surface of the fourth magnetic shield member 3382 facing the coupling surface 3322 of the support member 3320. The fourth magnetic member 3384 may include a fourth magnetic adsorption surface S4 accommodated in the fourth accommodation groove 3382b of the fourth magnetic shield member 3382 and exposed from the fourth accommodation groove 3382b. The third magnetic adsorption surface S3 of the third magnetic member 3374 and the fourth magnetic adsorption surface S4 of the fourth magnetic member 3384 corresponding thereto may generate a magnetic adsorption force, and accordingly, the upper electrode 3310 and the support member 3320 may be fastened to each other.

In an example embodiment, the third magnetic coupling member 3370 may be inserted into the second surface 3314 of the upper electrode 3310. A third seating groove 3314b, in which the third magnetic shield member 3372 is accommodated, may be disposed at the coupling point of the second surface 3314 of the upper electrode 3310. The opening direction of the third accommodation groove 3372b of the third magnetic shield member 3372 may be the same as the opening direction of the third seating groove 3314b. Accordingly, the third magnetic coupling member 3370 may be such that the third magnetic adsorption surface S3 of the third magnetic member 3374 may be exposed from the openings of the third accommodation groove 3372b and the third seating groove 3314b when the third magnetic shield member 3372 is disposed in the third seating groove 3314b. The fourth magnetic coupling member 3380 may be inserted into the coupling surface 3322 of the support member 3320. A fourth seating groove 3322b, in which the fourth magnetic shield member 3382 is accommodated, may be disposed at the coupling point of the coupling surface 3322 of the support member 3320. The opening direction of the fourth accommodation groove 3382b of the fourth magnetic shield member 3382 and the opening direction of the fourth seating groove 3322b may be the same. Accordingly, when the fourth magnetic shield member 3382 is disposed in the fourth seating groove 3322b, in the fourth magnetic coupling member 3380, the fourth magnetic adsorption surface S4 of the fourth magnetic member 3384 may be exposed from the openings of the fourth accommodation groove 3382b and the fourth seating groove 3322b and may be opposed to the third magnetic adsorption surface S3 of the third magnetic member 3374.

The plurality of third magnetic coupling members 3370 may be spaced apart from a gas supply hole for supplying gas on the second surface 3314 of the upper electrode 3310. That is, the plurality of third magnetic coupling members 3370 may be disposed in a region on the second surface 3314 of the upper electrode 3310 not interfering with the gas supply hole. The third magnetic shield member 3370 may be coupled to the third seating groove 3314b to be attached and detached by screw thread connection. The plurality of fourth magnetic coupling members 3380 may be spaced apart from a gas flow hole in communication with the gas supply hole on the coupling surface 3322 of the support member 3320. That is, the plurality of fourth magnetic coupling members 3380 may be disposed in a region on the coupling surface 3322 of the support member 3320 not interfering with the gas flow hole, and may be disposed in a position corresponding to the plurality of third magnetic coupling members 3370. The fourth magnetic shield member 3382 may be coupled to the fourth seating groove 3322b to be attached and detached by screw thread connection.

The third magnetic shield member 3372 of the third magnetic coupling member 3370 and the fourth magnetic shield member 3382 of the fourth magnetic coupling member 3380 may include the same material as the material of the first magnetic shield member 352 of the first magnetic coupling member 350 and the second magnetic shield member 362 of the second magnetic coupling member 360 described in the aforementioned example embodiment, and the overlapping description thereof will not be provided. Also, the third magnetic member 3374 of the third magnetic coupling member 3370 and the fourth magnetic member 3384 of the fourth magnetic coupling member 3380 may include the same material as the first magnetic member 354 of the first magnetic coupling member 350 and the second magnetic member 364 of the second magnetic coupling member 360 described in the aforementioned example embodiment, and the overlapping description thereof will not be provided.

In the description above, the third magnetic coupling member 3370 and the fourth magnetic coupling member 3380 may be configured in a cylindrical shape, but an example embodiment thereof is not limited thereto, and the third magnetic coupling member 3370 and the fourth magnetic coupling member 3380 may be configured in various shapes such as a polygonal columnal shape, an elliptical columnal shape, or the like, as long as the shape is able to implement point-coupling by magnetic adsorption force. Also, as illustrated in FIG. 10, the plurality of third magnetic coupling members 3370 may be spaced apart from the center of the upper electrode on the second surface of the upper electrode at the same distance (disposed on one virtual circle concentrically disposed with the center of the upper electrode), and the plurality of fourth magnetic coupling members 3380 may be spaced apart from the center of the support member on the coupling surface of the support member at the same distance, but an example embodiment thereof is not limited thereto, and the third magnetic coupling member and the fourth magnetic coupling member may be disposed in various manners in necessary positions of the upper electrode and the support member depending on actual conditions.

In the description above, the upper electrode 3310 and the support member 3320 may be fastened to each other by the magnetic adsorption force of the third magnetic coupling member 3370 and the fourth magnetic coupling member 3380 of the magnetic coupling device 3330 in the aforementioned example embodiment, but an example embodiment thereof is not limited thereto, and the upper electrode and the support member may be fastened to each other by the first magnetic coupling member, the second magnetic coupling member, the third magnetic coupling member and the fourth magnetic coupling member, which are described below.

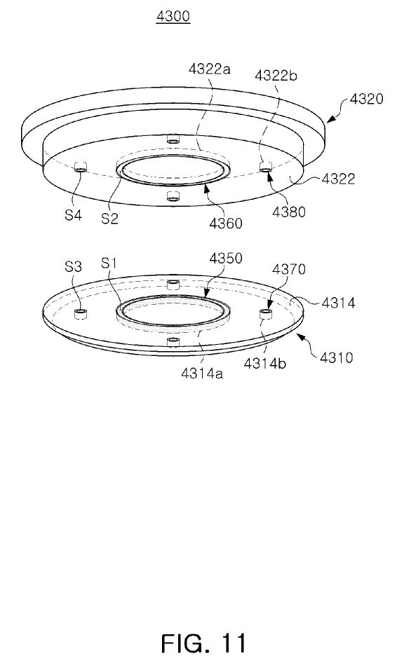

FIG. 11 is a diagram illustrating an upper electrode and a support member of a shower head according to an example embodiment.

Referring to FIG. 11, a shower head 4300 according to an example embodiment may include an upper electrode 4310, a support member 4320, and a magnetic coupling device 4330.

The upper electrode 4310 and the support member 4320 may include components included in the upper electrode 310 and the support member 320 described in the aforementioned example embodiment, and the overlapping description thereof will not be provided.

The magnetic coupling device 4330 may include a first magnetic coupling member 4350, a second magnetic coupling member 4360, a third magnetic coupling member 4370, and a fourth magnetic coupling member 4380.

The first magnetic coupling member 4350 and the third magnetic coupling member 4370 may be disposed on a second surface 4314 of the upper electrode 4310. The first magnetic coupling member 4350 may be disposed in the first seating groove 4314a formed on the second surface 4314 of the upper electrode 4310, and the third magnetic coupling member 4370 may be disposed in the third seating groove 4314b formed on the second surface 4314 of the upper electrode 4310. The second magnetic coupling member 4360 and the fourth magnetic coupling member 4380 may be disposed in the coupling surface 4322 of the support member 4320. The second magnetic coupling member 4360 may be disposed in the second seating groove 4322a formed on the coupling surface 4322 of the support member 4320, and the fourth magnetic coupling member 4380 may be disposed in the fourth seating groove 4322b formed on the coupling surface 4322 of the support member 4320. The first magnetic adsorption surface S1 of the first magnetic coupling member 4350 and the second magnetic adsorption surface S2 of the second magnetic coupling member 4360 may be magnetically coupled to each other, and the third magnetic adsorption surface S3 of the third magnetic coupling member 4370 and the fourth magnetic adsorption surface S4 of the fourth magnetic coupling member 4380 may be magnetically coupled to each other.

The components of the first magnetic coupling member 4350, the second magnetic coupling member 4360, the first seating groove 4314a of the upper electrode 4310 and the second seating groove 4322a of the support member 4320 may be applied the same as the components of the first magnetic coupling member 350, the second magnetic coupling member 360, the first seating groove 314a of the upper electrode 310 and the second seating groove 322a of the support member 320 described in the aforementioned example embodiment, and the overlapping description thereof will not be provided. The components of the third magnetic coupling member 4370, the fourth magnetic coupling member 4380, the third seating groove 4314b of the upper electrode 4310 and the fourth seating groove 4322b of the support member 4320 may be applied to the same as the components of the third magnetic coupling member 3370, the third magnetic coupling member 3380, the third seating groove 3314b of the upper electrode 3310 and the fourth seating groove 3322b of the support member 3320, and the overlapping description thereof will not be provided.

In FIG. 11, one first magnetic coupling member 4350, one second magnetic coupling member 4360, a plurality of third magnetic coupling members 4370 and a plurality of fourth magnetic coupling members 4380 are illustrated, but an example embodiment thereof is not limited thereto, and the plurality of first magnetic coupling member 1350 and the plurality of second magnetic coupling member 1360 described in the aforementioned example embodiment may include one third magnetic coupling member and one fourth magnetic coupling member.

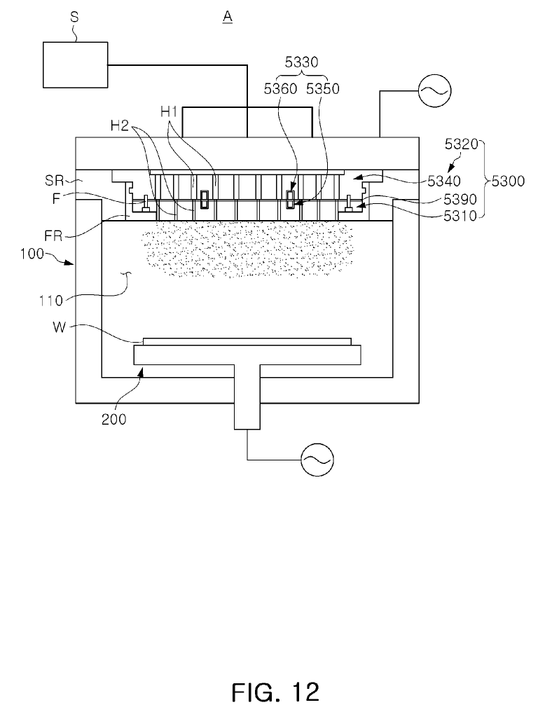

FIG. 12 is a diagram illustrating a plasma processing apparatus according to an example embodiment.

Referring to FIG. 12, a plasma processing apparatus A according to an example embodiment may include a chamber 100, a chuck 200, and a shower head 5300.

The components of the chamber 100 and the chuck 200 may be the same as the components of the chamber 100 and the chuck 200 described in the aforementioned example embodiment, and the overlapping description thereof will not be provided.

A plasma processing apparatus A according to an example embodiment may include the fastening member F and/or the fastening ring FR described in the aforementioned example embodiment.

The shower head 5300 may include an upper electrode 5310, a support member 5320, and a magnetic coupling device 5330.

The magnetic coupling device 5330 may include a first magnetic coupling member 5350 and a second magnetic coupling member 5360.

The upper electrode 5310 and the magnetic coupling device 5330 may be applied in the same manner as one of the upper electrodes 300, 1300, 3300, or 4300 and the magnetic coupling devices 330, 1330, 2330, 3330, and 4330 described in the description above, and the overlapping description thereof will not be provided.

The support member 5320 may include a cooling plate 5340 and a heat transfer sheet 5390. The cooling plate 5340 may be the same as the cooling plate 340 described in the description above. The heat transfer sheet 5390 may be disposed between the upper electrode 5310 and the cooling plate 5340. In this case, at least a portion of the coupling surface 5322 of the support member 5320 and the second surface 5314 of the upper electrode 5310 may be indirectly in contact with each other through a heat transfer sheet 5390. The heat transfer sheet 5390 may be formed of various thermal interface materials (TIM). The heat transfer sheet 5390 may have a through-hole formed in a portion corresponding to a position at which the magnetic coupling device 5330 is disposed. The influence of the magnetic adsorption force of the magnetic coupling device 5330 may be reduced through the through-hole. The heat transfer efficiency of the upper electrode 5310 and the support member 5320 may be further improved through the structure of the heat transfer sheet 5390.

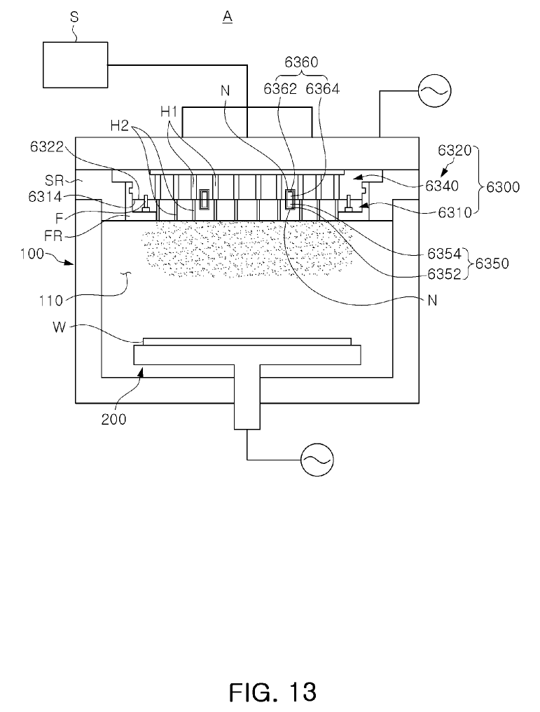

FIG. 13 is a diagram illustrating a plasma processing apparatus according to an example embodiment.

Referring to FIG. 13, a plasma processing apparatus A according to an example embodiment may include a chamber 100, a chuck 200, and a shower head 6300.

The components of the chamber 100 and the chuck 200 may be the same as the components of the chamber 100 and the chuck 200 described in the aforementioned example embodiment, and the overlapping description thereof will not be provided.

The shower head 6300 may include an upper electrode 6310, a support member 6320, a magnetic coupling device 6330, and an insert nut N. The support member 63200 may include a cooling plate 6340.

The upper electrode 6310, the support member 6320 and the magnetic coupling device 6330 may include components included in the upper electrode 310, the support member 320 and the magnetic coupling device 6330 described in the aforementioned example embodiment, and the overlapping description thereof will not be provided.

The magnetic coupling device 6330 may include a first magnetic shield member 6352 disposed in the first seating groove formed on the second surface 6314 of the upper electrode 6310, a first magnetic coupling member 6350 including the first magnetic member 6354 disposed in the first accommodation groove of the second magnetic shield member 6352, a second magnetic shield member 6362 disposed in the second seating groove formed on the coupling surface 6322 of the support member 6320, and a second magnetic coupling member 6360 including a second magnetic member 6364 disposed in the second accommodation groove of the second magnetic shield member 6354.

The first magnetic coupling member 6350 may be coupled to the first seating groove of the upper electrode 6310 through screw thread connection between the insert nut N disposed in the first seating groove of the upper electrode 6310 and the first magnetic shield member 6352. The second magnetic coupling member 6360 may be coupled to the second seating groove of the support member 6320 through the screw thread connection between the insert nut N disposed in the second seating groove of the support member 6320 and the second magnetic shield member 6362. The insert nut N may work as a washer for a fixing force shape, and may improve the usage lifespan by reducing damage to the upper electrode and the support member, and may ensure maintenance by replacing the insert nut N when damaged.

According to an example embodiment, a method of manufacturing a semiconductor device using the plasma processing apparatus may also be provided.

Using the method of manufacturing a semiconductor device, a substrate W using one of the plasma processing apparatus A described in the aforementioned example embodiments may be manufactured. The method of manufacturing a semiconductor device may include loading the substrate W into a chamber 100 in which shower heads 300, 1300, 3300, 4300, and 5300 are disposed in an upper portion of the chamber 100, supplying a first processing gas into the chamber 100 in which the substrate W is loaded through the shower head 300, 1300, 3300, 4300, and 5300, and exciting the processing gas into a plasma state to plasma process the substrate W. The plasma processing the substrate W may perform an etching process or a deposition process for plasma processing the substrate W.

Specifically, first, the method of manufacturing a semiconductor device may load the substrate W into the chamber 100 of the plasma processing apparatus A on which a deposition process or an etching process is to be performed. Here, the substrate W may be inserted into a processing space of the chamber 100 by a robot arm disposed in another chamber, such as a load lock chamber or a transfer chamber connected to the chamber 100 of the plasma processing apparatus A. The processing space of the chamber 100 may be configured to have a condition required for plasma processing of the substrate W. For example, when the substrate W is loaded into the chamber 100, the chamber 100 may be configured to have a vacuum pressure configured therein. Thereafter, a first processing gas may be supplied into the chamber 100 to which the substrate W is loaded, the first processing gas may be excited into a plasma state and a deposition process or an etching process for the substrate W may be performed. The deposition process or the etching process may perform an operation of forming a thin film on the substrate W using the first processing gas, or etching the thin film exposed by the mask film or the surface of the substrate W. In the method of manufacturing a semiconductor device, a process of cleaning the substrate W on which the process is completed may be performed. When the deposition process or the etching process or the cleaning process of the substrate W is completed, the substrate W may be unloaded in the chamber 100. Also, before unloading the substrate W in the method of manufacturing a semiconductor device, a purge gas may be supplied in the chamber 100 and may purge the internal region of the chamber 100. Accordingly, the first processing gas supplied in the chamber 100 may be removed.

A shower head according to the example embodiments, a plasma processing apparatus including the same, and a method of manufacturing a semiconductor device using the same may improve heat transfer efficiency of the shower head by allowing the shower head to maintain a uniform temperature, particularly, improving cooling efficiency, and processing efficiency for the substrate may improve.

According to the aforementioned example embodiments, a shower head which may improve heat transfer efficiency, a plasma processing apparatus including the shower head, and a method for manufacturing a semiconductor device using the same may be provided.

While the example embodiments have been illustrated and described above, it will be configured as apparent to those skilled in the art that modifications and variations could be made without departing from the scope of the present disclosure as defined by the appended claims.

What is claimed is:

1. A shower head, comprising:
an upper electrode having a first surface exposed to plasma and a second surface opposite to the first surface;
a support member having a coupling surface opposing the second surface of the upper electrode; and
a magnetic coupling device disposed on the second surface of the upper electrode and the coupling surface of the support member and magnetically coupling the upper electrode to the support member.

2. The shower head of claim 1,
wherein the magnetic coupling device includes a first magnetic coupling member disposed on the second surface of the upper electrode and a second magnetic coupling member disposed on the coupling surface of the support member and magnetically coupled to the first magnetic coupling member,
wherein the first magnetic coupling member includes a first magnetic shield member having a first accommodation groove formed in one surface of the first magnetic shield member facing the second surface of the upper electrode and a first magnetic member including a first magnetic adsorption surface accommodated in the first accommodation groove and exposed from the first accommodation groove, and
wherein the second magnetic coupling member includes a second magnetic shield member in which a second accommodation groove corresponding to the first accommodation groove is disposed on one surface of the second magnetic shield member facing the coupling surface of the support member, and a second magnetic member including a second magnetic adsorption surface accommodated in the second accommodation groove, exposed from the second accommodation groove and generating a magnetic adsorption force with the first magnetic adsorption surface.

3. The shower head of claim 2,
wherein a first seating groove in which the first magnetic shield member is accommodated is disposed on a second surface of the upper electrode, and an opening direction of the first accommodation groove is the same as an opening direction of the first accommodation groove, and
wherein a second seating groove in which the second magnetic shield member is accommodated is disposed on a coupling surface of the support member, and an opening direction of the second accommodation groove is the same as an opening direction of the second seating groove.

4. The shower head of claim 3,
wherein the one surface of the first magnetic shield member is positioned at a level lower than or at the same level as the second surface of the upper electrode in a height direction of the shower head, and
wherein the one surface of the second magnetic shield member is positioned at a level higher than or at the same level as the coupling surface of the support member in the height direction of the shower head.

5. The shower head of claim 3,
wherein the first magnetic adsorption surface of the first magnetic member is positioned at a level lower than or at the same level as the one surface of the first magnetic shield member in a height direction of the shower head, and
wherein a second magnetic adsorption surface of the second magnetic member is positioned at a level higher than or at the same level as the one surface of the second magnetic shield member in the height direction of the shower head.

6. The shower head of claim 3,
wherein the first magnetic adsorption surface of the first magnetic member is positioned at a level lower than the second surface of the upper electrode in a height direction of the shower head, and the one surface of the first magnetic shield member is positioned at a level between the first magnetic adsorption surface of the first magnetic member and the second surface of the upper electrode, and
wherein a second magnetic adsorption surface of the second magnetic member is positioned at a level higher than the coupling surface of the support member in the height direction of the shower head, and the one surface of the second magnetic shield member is positioned at a level between the second magnetic adsorption surface of the second magnetic member and the coupling surface of the support member.

7. The shower head of claim 3,
wherein the first magnetic shield member is configured to have a ring shape and is disposed concentrically with the shower head on the second surface of the upper electrode,
wherein the first accommodation groove is disposed in a ring shape on the one surface of the first magnetic shield member in a circumferential direction of the first magnetic shield member,
wherein the second magnetic shield member is configured to have a ring shape and is disposed concentrically with the shower head on the coupling surface of the support member, and
wherein the second accommodation groove is disposed in a ring shape on the one surface of the second magnetic shield member in a circumferential direction of the second magnetic shield member.

8. The shower head of claim 7,
wherein the first magnetic shield member is disposed to be attached to or detached from the first seating groove by a first fastening portion, and
wherein the second magnetic shield member is disposed to be attached to or detached from the second seating groove by a second fastening portion.

9. The shower head of claim 8, wherein the first fastening portion includes a first screw thread formed on at least one of an internal circumferential surface or an outer circumferential surface of the first magnetic shield member and a second screw thread formed on at least one of an internal circumferential surface or an outer circumferential surface of the first seating groove and screw-thread connected to the first screw thread.

10. The shower head of claim 8, wherein the second fastening portion includes a third screw thread formed on at least one of an internal circumferential surface or an outer circumferential surface of the second magnetic shield member and a fourth screw thread formed on at least one of an internal circumferential surface or an outer circumferential surface of the second seating groove and screw-thread connected to the third screw thread.

11. The shower head of claim 7,
wherein at least one first magnetic coupling member disposed adjacently to a central region of the upper electrode is disposed on the second surface of the upper electrode, and
wherein at least one second magnetic coupling member corresponding to the at least one first magnetic coupling member is disposed on the coupling surface of the support member.

12. The shower head of claim 11,
wherein a plurality of the first magnetic coupling members having different sizes are disposed concentrically with the shower head on the second surface of the upper electrode, and
wherein a plurality of the second magnetic coupling members corresponding to and magnetically coupled to the plurality of the first magnetic coupling members, respectively, are disposed on the coupling surface of the support member.

13. The shower head of claim 1,
wherein the magnetic coupling device includes a plurality of third magnetic coupling members disposed on a plurality of coupling points provided on a second surface of the upper electrode and a plurality of fourth magnetic coupling members disposed on a plurality of coupling points provided on the coupling surface of the support member and magnetically coupled to the plurality of third magnetic coupling members,
wherein each of the plurality of third magnetic coupling members includes a third magnetic shield member including a third accommodation groove formed in one surface of the third magnetic shield member facing the second surface of the upper electrode, and a third magnetic member including a third magnetic adsorption surface accommodated in the third accommodation groove and exposed from the third accommodation groove,
wherein each of the plurality of fourth magnetic coupling members includes a fourth magnetic shield member including a fourth accommodation groove formed in one surface of the fourth magnetic shield member facing the coupling surface of the support member and corresponding to the third accommodation groove, and a fourth magnetic member including a fourth magnetic adsorption surface accommodated in the fourth accommodation groove, exposed from the fourth accommodation groove and generating magnetic adsorption force with the third magnetic adsorption surface.

14. The shower head of claim 2, wherein the first magnetic member or the second magnetic member is configured as one of an alnico magnet, a samarium cobalt magnet or a neodymium magnet.

15. The shower head of claim 2, wherein the first magnetic shield member or the second magnetic shield member includes one of ferrite, mu-metal or supermalloy.

16. The shower head of claim 1, further comprising:
at least one of a fastening member connecting an outer edge of the upper electrode to an outer edge of the support member or a fastening ring disposed between an outer edge of the first surface of the upper electrode and an outer circumferential surface of the support member and connected to the support member.

17. The shower head of claim 1, wherein the support member includes a cooling plate including a refrigerant flow path through which a refrigerant flows and having the coupling surface.

18. The shower head of claim 17, wherein the support member further includes a heat transfer sheet disposed between the upper electrode and the cooling plate.

19. A plasma processing apparatus, comprising:
a chamber having a processing space;
a chuck disposed in the processing space of the chamber, supporting a substrate and including a lower electrode; and
a shower head disposed in an upper portion of the chamber and opposing the chuck,
wherein the shower head includes:
an upper electrode having a first surface exposed to plasma and a second surface opposite to the first surface;
a cooling plate having a coupling surface opposing the second surface of the upper electrode; and
a magnetic coupling device disposed between the second surface of the upper electrode and the coupling surface of the cooling plate and magnetically coupling the upper electrode to the cooling plate.

20. A method of manufacturing a semiconductor device, the method comprising:
loading a substrate into a chamber including a shower head disposed in an upper portion of the chamber; and
supplying a processing gas through the shower head into the chamber in which the substrate is loaded, exciting the processing gas in a plasma state and plasma-processing the substrate,
wherein the shower head includes:
an upper electrode having a first surface exposed to plasma and a second surface opposite to the first surface;
a support member having a coupling surface opposing the second surface of the upper electrode; and
a magnetic coupling device disposed on the second surface of the upper electrode and the coupling surface of the support member and magnetically coupling the upper electrode to the support member.
